(19) United States
(12) Patent Application Publication
(10) Pub. No.: US 2026/0311978 A1
(43) Pub. Date: Oct. 8, 2026

(54) Sputtering System with a Plasma Monitoring Device and an Ion Source

(71) Applicant: DAH YOUNG VACUUM EQUIPMENT CO., LTD., TAICHUNG CITY (TW)

(72) Inventors: Tzu-Hou CHAN, TAICHUNG CITY (TW); Ching-Yen LIN, TAICHUNG CITY (TW); Chu-Liang HO, TAICHUNG CITY (TW); Ping-Yen HSIEH, TAICHUNG CITY (TW); Ying-Hung CHEN, TAICHUNG CITY (TW)

(21) Appl. No.: 19/699,380

(22) Filed: Jun. 5, 2026

Related U.S. Application Data
(63) Continuation-in-part of application No. 18/354,609, filed on Jul. 18, 2023.

(30) Foreign Application Priority Data
Apr. 27, 2023 (TW) 112115684

(51) Int. Cl. H01J 37/34; C23C 14/34; C23C 14/54; H01J 37/32

(52) U.S. Cl. CPC H01J 37/3435; C23C 14/3407; C23C 14/3464; C23C 14/54; H01J 37/32449; H01J 37/3299; H01J 2237/332

(57) ABSTRACT

A sputtering system with a plasma monitoring device and an ion source includes: first and second target holders providing first and second plasmas; a first mass flow controller set supplying gas to target holders; a plasma emission monitor adjusting gas flow rate based on plasma spectrum of the plasma, a total number of collimator sets is less than that of target holders; a deposition target carrier connected to the hollow chamber; a rotary driver connected to the deposition target carrier; a plasma source providing induced electric field to ionize the gas; and an ion source device providing an ion beam, the rotary driver has a rotation direction, the ion source device is located on a front side of the rotation direction relative to the plasma source, and the plasma source is located on a rear side of the rotation direction relative to the ion source device.

### CROSS REFERENCE TO RELATED APPLICATION

This application is a continuation in part of U.S. patent application Ser. No. 18/354,609, and claims the earliest filing date of Jul. 18, 2023, the entire specifications of which are incorporated herein by reference.

### BACKGROUND

### Field of the Invention

The present invention relates to a sputtering system with a plasma monitoring device and an ion source, and more particularly to a sputtering system with a plasma monitoring device and an ion source that can save costs and reduce system complexity.

### Description of Related Art

Currently, a standard sputtering system equipped with a plasma monitoring device and an ion source at least includes: one target, one set of optical collimators corresponding to the number of targets, one set of mass flow controllers (MFCs) equal in number to the optical collimator sets, and one set of gas supply tubes equal in number to the optical collimator sets. Within each set of optical collimators, each set of MFCs, and each set of gas supply tubes, there are additionally 2 to 4 optical collimators, 2 to 4 MFCs, and 2 to 4 gas supply tubes, respectively, depending on the length of the target.

However, current mass-production sputtering equipment often employs four targets in a batch configuration to increase throughput. Consequently, a sputtering system with a plasma monitoring device and an ion source used in such mass-production equipment would require at least four sets of optical collimators (8 to 16 optical collimators) corresponding to the number of targets, four sets of MFCs (8 to 16 MFCs) equal in number to the optical collimator sets, and four sets of gas supply tubes (8 to 16 gas supply tubes) equal in number to the optical collimator sets. As a result, users cannot afford the substantial cost of such a sputtering system with a plasma monitoring device and an ion source.

### SUMMARY

The present invention provides a sputtering system with a plasma monitoring device and an ion source, which has the effects of saving costs and reducing system complexity.
at least one first target holder located in a hollow chamber, the first target holder having a first target material and providing a first plasma;
at least one second target holder located in a hollow chamber, the second target holder having a second target material and providing a second plasma;
a first collimator set disposed corresponding to the first target holder to detect a first plasma spectrum of the first plasma;
a first mass flow controller set supplying gas to the first target holder and the second target holder through a first gas supply tube set and a second gas supply tube set, respectively;
a plasma emission monitor adjusting a flow rate of the gas provided by the first mass flow controller set according to the first plasma spectrum of the first plasma, wherein the first target material and the second target material are the same, and a total number of collimator sets is less than a total number of target holders, the first target holder corresponds to the independently disposed first gas supply tube set, and the second target holder corresponds to the independently disposed second gas supply tube set, a total number of gas supply tube sets is equal to the total number of target holders, the total number of gas supply tube sets is greater than the total number of collimator sets, and the total number of gas supply tube sets is greater than a total number of mass flow controller sets;
a deposition target carrier connected to the hollow chamber and configured to carry a deposition target;
a rotary driver rotatably connected to the deposition target carrier;
a plasma source connected to the hollow chamber and configured to provide an induced electric field to ionize the gas; and
an ion source device configured to provide an ion beam, wherein the rotary driver has a rotation direction, the ion source device is located on a front side of the rotation direction relative to the plasma source, and the plasma source is located on a rear side of the rotation direction relative to the ion source device.

In one embodiment of the present invention, the total number of collimator sets is equal to 1, and the total number of target holders is greater than or equal to 2.

In one embodiment of the present invention, the total number of mass flow controller sets is less than the total number of target holders.

In one embodiment of the present invention, the total number of mass flow controller sets is equal to 1, and the total number of target holders is greater than or equal to 2.

In one embodiment of the present invention, a first light intensity of the first plasma of the first target holder is the same as a second light intensity of the second plasma of the second target holder.

In one embodiment of the present invention, a difference between a first light intensity of the first plasma of the first target holder and a second light intensity of the second plasma of the second target holder is within 10%.

In one embodiment of the present invention, the above-mentioned sputtering system further comprises: at least one third target holder having a third target material and providing a third plasma; a second collimator set disposed corresponding to the third target holder to detect a third light intensity of the third plasma of the third target holder; and a second mass flow controller set supplying another gas to the third target holder through a third gas supply tube set, wherein the first target material is different from the third target material, and the total number of collimator sets is less than the total number of target holders.

In one embodiment of the present invention, the total number of collimator sets is equal to 2, and the total number of target holders is greater than or equal to 3.

In one embodiment of the present invention, the total number of mass flow controller sets is less than the total number of target holders.

In one embodiment of the present invention, the total number of mass flow controller sets is equal to 2, and the total number of target holders is greater than or equal to 3.

Based on the above, in the sputtering system according to an embodiment of the present invention, since the first light intensity of the first plasma of the first target holder can still be substantially the same as the second light intensity of the second plasma of the second target holder under the condition of reducing the total number of collimator sets or mass flow controller sets, the sputtering system with a plasma monitoring device and an ion source according to an embodiment of the present invention can be used to replace a conventional sputtering system with a plasma monitoring device and an ion source, thereby achieving the effects of saving costs or reducing system complexity.

Furthermore, in an embodiment of the present invention, the ion source device is additionally installed on the opposite side of the plasma source with respect to the rotation direction. The ion source device provides a stable high-energy ion beam, which greatly increases the density of the deposited film layer, thereby achieving the effect of improving film quality.

In order to make the above-mentioned features and advantages of the present invention more comprehensible, embodiments are described in detail below with reference to the accompanying drawings.

### BRIEF DESCRIPTION OF THE DRAWINGS

FIG. 1 is a schematic structural diagram of a sputtering system with a plasma monitoring device and an ion source according to an embodiment of the present invention;

FIG. 2 is a schematic structural diagram of a sputtering system with a plasma monitoring device and an ion source according to another embodiment of the present invention;

FIG. 3A is a schematic structural diagram of a sputtering system with a plasma monitoring device and an ion source of a control group;

FIG. 3B is a schematic structural diagram of a sputtering system with a plasma monitoring device and an ion source of an experimental group;

FIG. 4 is a schematic structural diagram of a sputtering system with a plasma monitoring device and an ion source according to an embodiment of the present invention;

FIG. 5 is a schematic structural diagram of a sputtering system with a plasma monitoring device and an ion source according to an embodiment of the present invention;

FIG. 6 shows plasma spectra of two targets when the plasma light intensity is preset to 5000 photon counts in the control group;

FIG. 7 shows plasma spectra of two targets when the plasma light intensity is preset to 5000 photon counts in the experimental group;

FIG. 8 shows plasma spectra of two targets when the plasma light intensity is preset to multiple photon counts in the control group; and

FIG. 9 shows plasma spectra of two targets when the plasma light intensity is preset to multiple photon counts in the experimental group.

### DETAILED DESCRIPTION

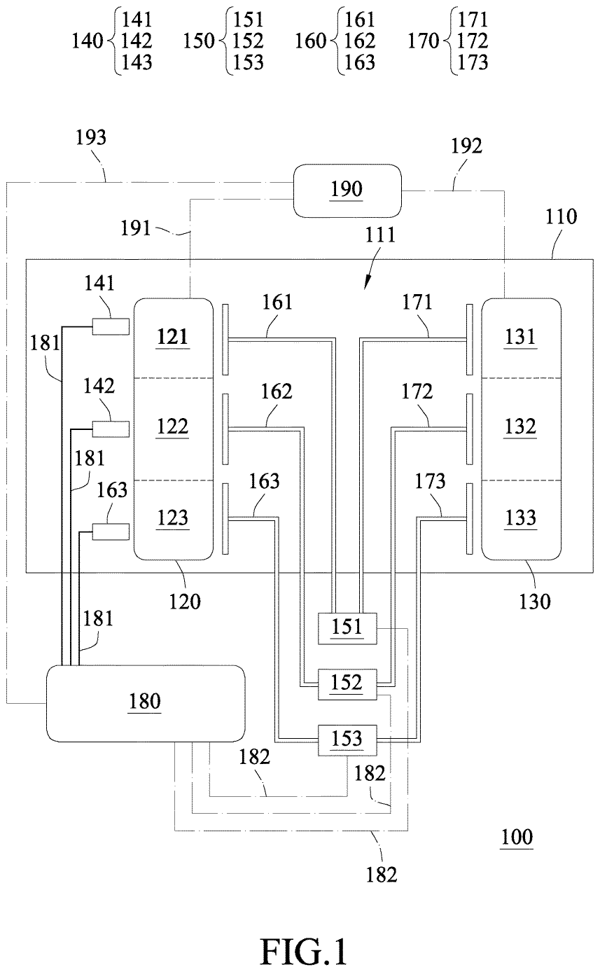

FIG. 1 is a schematic structural diagram of a sputtering system with a plasma monitoring device and an ion source according to an embodiment of the present invention. Referring to FIG. 1, the sputtering system 100 with a plasma monitoring device and an ion source of the present embodiment includes a hollow chamber 110, at least one first target holder 120 (FIG. 1 schematically shows one as an example, but the invention is not limited thereto), at least one second target holder 130 (FIG. 1 schematically shows one as an example, but the invention is not limited thereto), a first collimator set 140, a first mass flow controller set 150, a first gas supply tube set 160, a second gas supply tube set 170, a plasma emission monitor 180, and a power supply 190. The first target holder 120, the second target holder 130, the first collimator set 140, the first gas supply tube set 160, and the second gas supply tube set 170 are disposed inside the hollow chamber 110, while the first mass flow controller set 150, the plasma emission monitor 180, and the power supply 190 are disposed outside the hollow chamber 110, but the invention is not limited thereto. In this embodiment, the sputtering system 100 with a plasma monitoring device and an ion source can be used, for example, in a vacuum plasma process to detect, diagnose, and adjust plasma conditions, thereby achieving stable plasma and overall uniformity.

Specifically, in this embodiment, the hollow chamber 110 has an accommodating space 111. A vacuum system (not shown) composed of various vacuum pumps can create a vacuum in the accommodating space 111, so that the accommodating space 111 can be in a vacuum state.

The first target holder 120 is disposed on the left side of the accommodating space 111. Referring to FIG. 1, the first target holder 120 includes, from top to bottom, an upper region 121, a middle region 122, and a lower region 123. The first target holder 120 has a first target material and can provide a first plasma. In this embodiment, the first target material can be, for example, titanium, and the first plasma can be, for example, titanium atoms or ionized titanium ions, but the invention is not limited thereto.

The second target holder 130 is disposed on the right side of the accommodating space 111. Referring to FIG. 1, the second target holder 130 includes, from top to bottom, an upper region 131, a middle region 132, and a lower region 133. The second target holder 130 has a second target material and can provide a second plasma. The second target material may be the same as the first target material, but the invention is not limited thereto. In this embodiment, the second target material can be, for example, titanium, and the second plasma can be, for example, titanium atoms or ionized titanium ions, but the invention is not limited thereto. In this embodiment, the total number of target holders (i.e., the first target holder 120 and the second target holder 130) is 2, but the invention is not limited thereto.

The first collimator set 140 is disposed on the left side of the first target holder 120, but the invention is not limited thereto. The first collimator set 140 can be arranged corresponding to the first target holder 120 to detect a first plasma spectrum of the first plasma provided by the first target holder 120. In this embodiment, referring to FIG. 1, the first collimator set 140 may include collimators 141, 142, and 143, but the invention is not limited thereto. The collimator 141 is disposed corresponding to the upper region 121 of the first target holder 120 to detect the first plasma spectrum of the first plasma in the upper region 121. The collimator 142 is disposed corresponding to the middle region 122 of the first target holder 120 to detect the first plasma spectrum of the first plasma in the middle region 122. The collimator 143 is disposed corresponding to the lower region 123 of the first target holder 120 to detect the first plasma spectrum of the first plasma in the lower region 123. For example, when the first target material of the first target holder 120 is titanium, the first collimator set 140 can be used to detect the light intensity (i.e., the number of photons) of ionized titanium ions at a wavelength of 453.6 nm. In some embodiments, the first collimator set may also detect light intensities at other wavelengths according to the characteristics of other atoms or ions to be detected. Furthermore, in this embodiment, the total number of collimator sets (i.e., the first collimator set 140) is 1, but the invention is not limited thereto.

The first mass flow controller set 150 is disposed on one side outside the hollow chamber 110, the first gas supply tube set 160 is disposed on the right side of the first target holder 120, and the second gas supply tube set 170 is disposed on the left side of the second target holder 130, but the invention is not limited thereto. Referring to FIG. 1, the first mass flow controller set 150 can be respectively connected to the first gas supply tube set 160 and the second gas supply tube set 170, and the first mass flow controller set 150 can supply gas to the first target holder 120 and the second target holder 130 through the first gas supply tube set 160 and the second gas supply tube set 170, respectively. In detail, in this embodiment, the first mass flow controller set 150 may include mass flow controllers 151, 152, and 153; the first gas supply tube set 160 may include gas supply tubes 161, 162, and 163; and the second gas supply tube set 170 may include gas supply tubes 171, 172, and 173, but the invention is not limited thereto. The mass flow controller 151 is connected to the gas supply tubes 161 and 171, respectively; the mass flow controller 152 is connected to the gas supply tubes 162 and 172, respectively; and the mass flow controller 153 is connected to the gas supply tubes 163 and 173, respectively. The gas supply tubes 161, 162, and 163 are disposed corresponding to the upper region 121, the middle region 122, and the lower region 123 of the first target holder 120, respectively. The gas supply tubes 171, 172, and 173 are disposed corresponding to the upper region 131, the middle region 132, and the lower region 133 of the second target holder 130, respectively. Furthermore, in this embodiment, the gas may include oxygen (O₂), but the invention is not limited thereto. In this embodiment, the total number of mass flow controller sets (i.e., the first mass flow controller set 150) may be 1, but the invention is not limited thereto.

The plasma emission monitor (PEM) 180 is disposed on one side outside the hollow chamber 110. The plasma emission monitor 180 can adjust the flow rate of the gas provided by the first mass flow controller set 150 according to the first plasma spectrum. In detail, referring to FIG. 1, the plasma emission monitor 180 may include optical fibers 181 and signal lines 182. The optical fibers 181 can be connected to the first collimator set 140, and the signal lines 182 can be connected to the first mass flow controller set 150. In this embodiment, the plasma emission monitor 180 can first receive the first plasma spectrum detected by the first collimator set 140 through the optical fiber 181, then analyze the signal of the first plasma spectrum (e.g., the light intensity of the plasma), and then adjust the flow rate of the gas provided by the first mass flow controller set 150 through the signal line 182 according to the analysis result of the first plasma spectrum, so as to uniformly distribute the plasma by controlling the atmosphere concentration, thereby stabilizing the process. In this embodiment, since the first target holder 120 and the second target holder 130 share the same mass flow controller set (i.e., the first mass flow controller set 150), the flow rate of the gas supplied by the first mass flow controller set 150 to the first target holder 120 should be substantially the same as that supplied to the second target holder 130, and the flow rate of the gas received by the first target holder 120 should also be substantially the same as that received by the second target holder 130.

For example, when the light intensity presented by the plasma spectrum of the upper region 121 of the first target holder 120 is lower than the light intensities presented by the plasma spectra of the middle region 122 and the lower region 123, the plasma emission monitor 180 can respectively control the flow rates of the gas provided by the mass flow controllers 151, 152, and 153 through different signal lines 182, so that the light intensities presented by the plasma spectra of the upper region 121, the middle region 122, and the lower region 123 of the first target holder 120 are substantially the same, and the light intensities presented by the plasma spectra of the upper region 131, the middle region 132, and the lower region 133 of the second target holder 130 are also substantially the same. When the light intensity presented by the plasma spectrum of the upper region 121 (or the middle region 122 or the lower region 123) of the first target holder 120 is different from a preset value, the plasma emission monitor 180 can control the flow rate of the gas provided by the corresponding mass flow controller 151 (or 152 or 153) through the corresponding signal line 182, so that the light intensity presented by the plasma spectrum of the upper region 121 (or the middle region 122 or the lower region 123) of the first target holder 120 is substantially the same as the preset value, and the light intensity presented by the plasma spectrum of the upper region 131 (or the middle region 132 or the lower region 133) of the second target holder 130 is also substantially the same as the preset value. Therefore, in the sputtering system 100 with a plasma monitoring device and an ion source of the present embodiment, the first light intensity of the first plasma of the first target holder 120 may be, for example, substantially the same as the second light intensity of the second plasma of the second target holder 130, but the invention is not limited thereto. In some embodiments, the difference between the first light intensity of the first plasma of the first target holder 120 and the second light intensity of the second plasma of the second target holder 130 may be, for example, within 10%, but the invention is not limited thereto.

Referring to FIG. 1, the power supply 190 may include power output lines 191, 192, and a power signal line 193. The power output line 191 can be connected to the first target holder 120, the power output line 192 can be connected to the second target holder 130, and the power signal line 193 can be connected to the plasma emission monitor 180. The power supply 190 may be of a direct current (DC), medium frequency (MF), radio frequency (RF), or high-power impulse magnetron sputtering (HiPIMS) type, but the invention is not limited thereto.

In this embodiment, referring to FIG. 1, the first target material and the second target material are the same; the total number of collimator sets (i.e., the first collimator set 140) may be less than the total number of target holders (i.e., the first target holder 120 and the second target holder 130); the total number of mass flow controller sets (i.e., the first mass flow controller set 150) may be less than the total number of target holders (i.e., the first target holder 120 and the second target holder 130); and the total number of collimator sets (i.e., the first collimator set 140) may be equal to the total number of mass flow controller sets (i.e., the first mass flow controller set 150).

Although the total number of target holders (i.e., the first target holder 120 and the second target holder 130) in this embodiment is 2, the present invention does not limit the total number of target holders. In some embodiments, the total number of target holders may be greater than or equal to 3.

Although the number of collimators in the first collimator set 140 in this embodiment is 3, the present invention does not limit the number of collimators in a collimator set. In some embodiments, the number of collimators in a collimator set may also be 1, 2, or greater than 3. In some embodiments, the number of collimators in a collimator set may also depend on the length of the target holder.

Although the number of mass flow controllers in the first mass flow controller set 150 in this embodiment is 3, the present invention does not limit the number of mass flow controllers in a mass flow controller set. In some embodiments, the number of mass flow controllers in a mass flow controller set may also be 1, 2, or greater than 3.

Furthermore, compared to a conventional sputtering system with a plasma monitoring device and an ion source that has two target holders and requires two collimator sets and two mass flow controller sets, the sputtering system 100 with a plasma monitoring device and an ion source of the present embodiment requires only one collimator set and one mass flow controller set, thereby achieving the effects of reducing system complexity and saving costs. Moreover, in some embodiments, even if the total number of target holders is greater than 2, as long as the target materials of all target holders are the same, only one first collimator set 140 and one first mass flow controller set 150 need to be provided.

Other embodiments will be listed below for illustration. It should be noted that the following embodiments adopt the component reference numerals and part of the content of the preceding embodiments, wherein the same reference numerals are used to denote the same or similar components, and descriptions of the same technical content are omitted. For descriptions of the omitted parts, reference may be made to the preceding embodiments, and the following embodiments will not repeat them in detail.

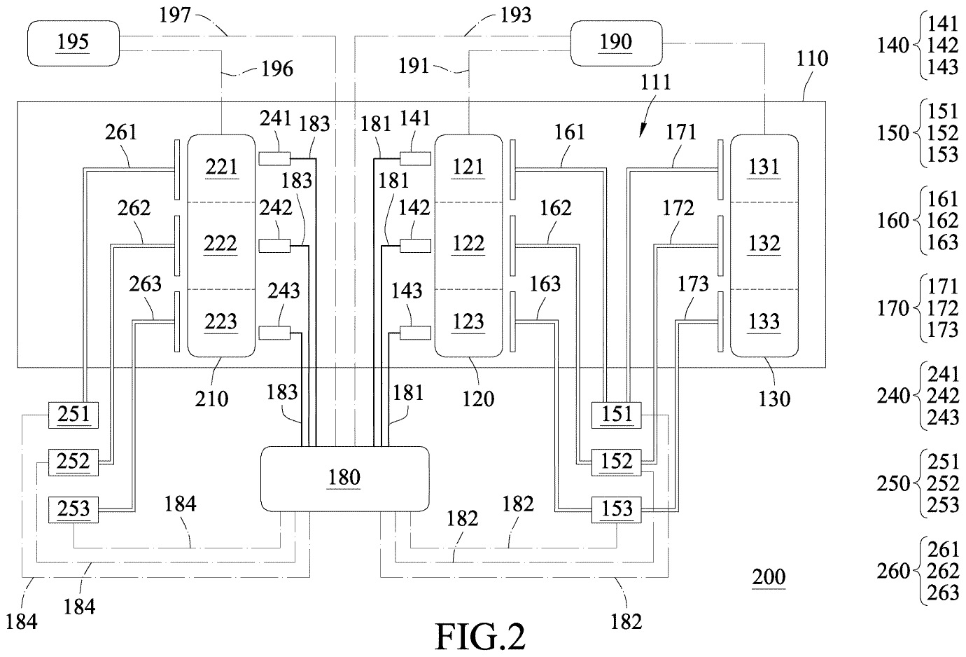

FIG. 2 is a schematic structural diagram of a sputtering system with a plasma monitoring device and an ion source according to another embodiment of the present invention. Referring to both FIG. 1 and FIG. 2, the sputtering system 200 with a plasma monitoring device and an ion source of the present embodiment is similar to the sputtering system 100 with a plasma monitoring device and an ion source of FIG. 1, except that the sputtering system 200 with a plasma monitoring device and an ion source of the present embodiment further includes at least one third target holder 210, a second collimator set 240, a second mass flow controller set 250, a third gas supply tube set 260, and a power supply 195, and a third target material of the third target holder 210 may be different from the first target material and the second target material.

Referring to FIG. 2, in the sputtering system 200 with a plasma monitoring device and an ion source of the present embodiment, the third target holder 210 and the second collimator set 240 are disposed inside the hollow chamber 110, and the second mass flow controller set 250 is disposed outside the hollow chamber 110, but the invention is not limited thereto.

Specifically, referring to FIG. 2, the third target holder 210 is disposed on the left side of the accommodating space 111, and the first target holder 120 is disposed between the third target holder 210 and the second target holder 130, but the invention is not limited thereto. The third target holder 210 includes, from top to bottom, an upper region 211, a middle region 212, and a lower region 213. The third target holder 210 has a third target material and can provide a third plasma. The third target material may be different from the first target material and the second target material, but the invention is not limited thereto. In this embodiment, the third target material can be, for example, chromium, and the third plasma can be, for example, chromium atoms, chromium molecules, or ionized chromium ions, but the invention is not limited thereto. In this embodiment, the total number of target holders (i.e., the first target holder 120, the second target holder 130, and the third target holder 210) is 3, but the invention is not limited thereto.

The second collimator set 240 is disposed on the right side of the third target holder 210, but the invention is not limited thereto. Referring to FIG. 2, the second collimator set 240 can be arranged corresponding to the third target holder 210 to detect a third plasma spectrum of the third plasma provided by the third target holder 210. In this embodiment, the second collimator set 240 may include collimators 241, 242, and 243, but the invention is not limited thereto. The collimator 241 is disposed corresponding to the upper region 211 of the third target holder 210 to detect the third plasma spectrum of the third plasma in the upper region 211. The collimator 242 is disposed corresponding to the middle region 212 of the third target holder 210 to detect the third plasma spectrum of the third plasma in the middle region 212. The collimator 243 is disposed corresponding to the lower region 213 of the third target holder 210 to detect the third plasma spectrum of the third plasma in the lower region 213. In this embodiment, the total number of collimator sets (i.e., the first collimator set 140 and the second collimator set 240) is 2, but the invention is not limited thereto.

Referring to FIG. 2, the second mass flow controller set 250 is disposed on one side outside the hollow chamber 110, and the third gas supply tube set 260 is disposed on the left side of the third target holder 210, but the invention is not limited thereto. The second mass flow controller set 250 can be connected to the third gas supply tube set 260, and the second mass flow controller set 250 can supply gas to the third target holder 210 through the third gas supply tube set 260. In detail, in this embodiment, the second mass flow controller set 250 may include mass flow controllers 251, 252, and 253, and the third gas supply tube set 260 may include gas supply tubes 261, 262, and 263, but the invention is not limited thereto. The mass flow controllers 251, 252, and 253 are connected to the gas supply tubes 261, 262, and 263, respectively. The gas supply tubes 261, 262, and 263 are disposed corresponding to the upper region 211, the middle region 212, and the lower region 213 of the third target holder 210, respectively. Furthermore, in this embodiment, the gas may include oxygen, but the invention is not limited thereto. In this embodiment, the total number of mass flow controller sets (i.e., the first mass flow controller set 150 and the second mass flow controller set 250) may be 2, but the invention is not limited thereto.

The power supply 195 may include a power output line 196 and a power signal line 197. The power output line 196 can be connected to the third target holder 210, and the power signal line 197 can be connected to the plasma emission monitor 180. The power supply 195 may be of a DC, MF, RF, or HiPIMS type, but the invention is not limited thereto.

In the sputtering system 200 with a plasma monitoring device and an ion source of the present embodiment, the plasma emission monitor 180 may further include optical fibers 183 and signal lines 184. The optical fibers 183 can be connected to the second collimator set 240, and the signal lines 184 can be connected to the second mass flow controller set 250.

In the sputtering system 200 with a plasma monitoring device and an ion source of the present embodiment, the first target material and the second target material are the same, and the first target material is different from the third target material; the total number of collimator sets (i.e., the first collimator set 140 and the second collimator set 240) may be less than the total number of target holders (i.e., the first target holder 120, the second target holder 130, and the third target holder 210); the total number of mass flow controller sets (i.e., the first mass flow controller set 150 and the second mass flow controller set 250) may be less than the total number of target holders (i.e., the first target holder 120, the second target holder 130, and the third target holder 210); and the total number of collimator sets (i.e., the first collimator set 140 and the second collimator set 240) may be equal to the total number of mass flow controller sets (i.e., the first mass flow controller set 150 and the second mass flow controller set 250).

Furthermore, unlike the sputtering system 100 with a plasma monitoring device and an ion source of FIG. 1, since the sputtering system 200 with a plasma monitoring device and an ion source of the present embodiment has another type of target material, an additional collimator set and mass flow controller set are required. That is, unlike a conventional sputtering system with a plasma monitoring device and an ion source, in the sputtering system with a plasma monitoring device and an ion source designed in this embodiment, the total number of collimator sets and the total number of mass flow controller sets are adjusted according to the number (or types) of target materials. The total number of collimator sets is the same as the number (or types) of target materials, and the total number of mass flow controller sets is also the same as the number (or types) of target materials.

Below the sputtering system with a plasma monitoring device and an ion source of the above embodiments will be described in detail by way of experimental examples. However, the following experimental examples are not intended to limit the present invention.

[Experimental Example]: Confirm whether the light intensities of the plasmas provided by the two target holders in the sputtering system with a plasma monitoring device and an ion source of the experimental group are substantially the same or differ within 10%.

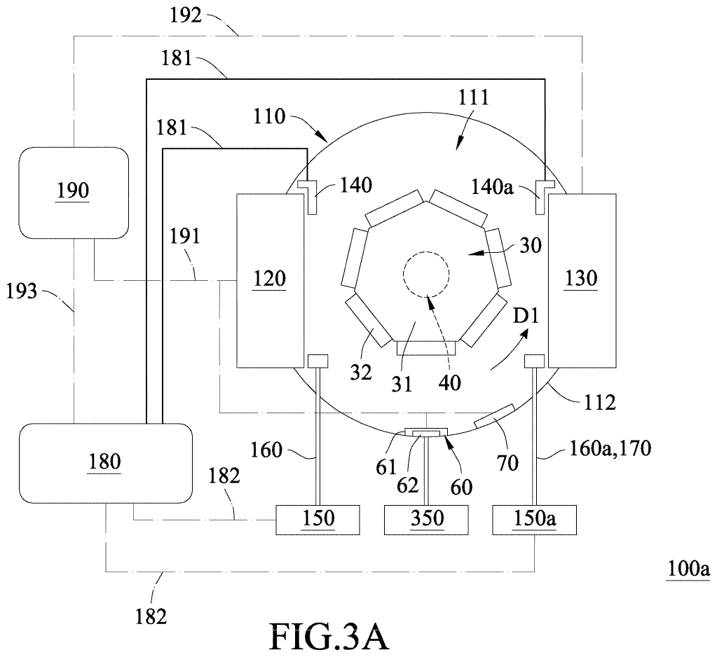

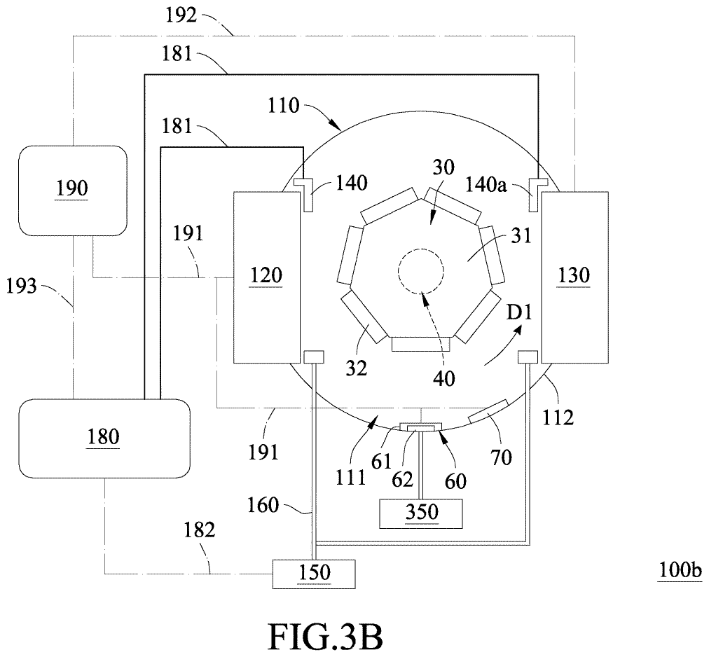

First, please refer to FIG. 3A, which is a schematic structural diagram of a sputtering system with a plasma monitoring device and an ion source of a control group. The sputtering system 100a with a plasma monitoring device and an ion source of the control group includes at least two target holders containing titanium (i.e., the first target holder 120 and the second target holder 130), two collimator sets corresponding to the number of target holders (i.e., the first collimator set 140 and the first collimator set 140a), two mass flow controller sets equal in number to the collimator sets (i.e., the first mass flow controller set 150 and the first mass flow controller set 150a), two gas supply tube sets equal in number to the collimator sets (i.e., the first gas supply tube set 160 and the first gas supply tube set 160a), and a mass flow controller 350 for providing argon (Ar). That is, the sputtering system 100a with a plasma monitoring device and an ion source of the control group can be regarded as aconventional sputtering system with a plasma monitoring device and an ion source.

Next, please refer to FIG. 3B, which is a schematic structural diagram of a sputtering system with a plasma monitoring device and an ion source of an experimental group. The sputtering system 100b with a plasma monitoring device and an ion source of the experimental group includes at least two target holders containing titanium (i.e., the first target holder 120 and the second target holder 130), one collimator set (i.e., the first collimator set 140), one mass flow controller set (i.e., the first mass flow controller set 150), two gas supply tube sets (i.e., the first gas supply tube set 160 and the first gas supply tube set 160a), and a mass flow controller 350 for providing argon (Ar). That is, the sputtering system 100b with a plasma monitoring device and an ion source of the experimental group has one less first collimator set 140a and one less first mass flow controller set 150a than the sputtering system 100a with a plasma monitoring device and an ion source of the control group, and the sputtering system 100b with a plasma monitoring device and an ion source of the experimental group can be regarded as a sputtering system with a plasma monitoring device and an ion source according to an embodiment of the present invention. Furthermore, although FIG. 3B shows the first collimator set 140a, the first collimator set 140a here is only used to detect and confirm whether the second light intensity of the second plasma of the second target holder 130 is substantially the same as or differs within 10% from the first light intensity of the first plasma of the first target holder 120. That is, the detection result of the first collimator set 140a here will not be used as a basis for adjusting the flow rate of oxygen by the sputtering system 100b with a plasma monitoring device and an ion source, and the first collimator set 140a is not a conventional configuration of an embodiment of the present invention and can be omitted.

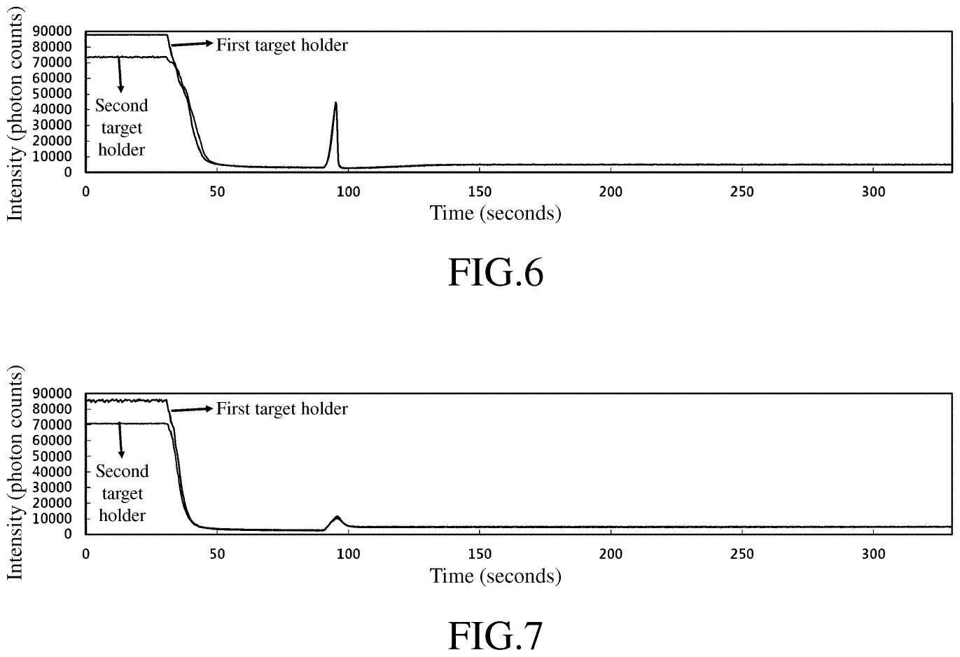

Then, please refer to both FIG. 6 and FIG. 7. FIG. 6 shows the plasma spectra of the two target holders in the control group when the light intensity of the plasma is preset to 5000 photon counts. FIG. 7 shows the plasma spectra of the two target holders in the experimental group when the light intensity of the plasma is preset to 5000 photon counts.

FIG. 6 and FIG. 7 show the results of detecting the plasma spectra at a wavelength of 453.6 nm (i.e., ionized titanium ions) of the plasmas provided by the two target holders. In the figures, the period from 0 to 30 seconds is the plasma spectrum of the plasma when no oxygen is provided; the period from 30 to 90 seconds is the plasma spectrum of the plasma when a fixed flow rate of oxygen is provided; and the period from 90 to 390 seconds is the plasma spectrum when the flow rate of oxygen is adjusted according to the preset value (5000 photon counts) and real-time monitoring results. Additionally, the light intensities (photon counts) of the plasma detected at specific times in FIG. 6 are recorded in Table 1 below, and the light intensities (photon counts) of the plasma detected at specific times in FIG. 7 are recorded in Table 2 below.

TABLE 1

| | 30 s | 55 s | 90 s | 150 s | 210 s | 270 s | 330 s |
|---|---|---|---|---|---|---|---|
| First target | 87891 cts | 4326 cts | 3057 cts | 5125 cts | 5080 cts | 4980 cts | 4997 cts |
| holder | | | | | | | |
| Second target | 73766 cts | 4187 cts | 2927 cts | 5108 cts | 4797 cts | 4947 cts | 5059 cts |
| holder | | | | | | | |

TABLE 2

| | 30 s | 55 s | 90 s | 150 s | 210 s | 270 s | 330 s |
|---|---|---|---|---|---|---|---|
| First target | 85454 cts | 3414 cts | 2846 cts | 5044 cts | 4858 cts | 4990 cts | 4981 cts |
| holder | | | | | | | |
| Second target | 70638 cts | 3095 cts | 2495 cts | 4719 cts | 4683 cts | 4742 cts | 4881 cts |
| holder | | | | | | | |

From the results in Tables 1 and 2, it can be seen that in the period from 30 to 90 seconds of either the control group or the experimental group, providing a fixed flow rate of oxygen causes the light intensity of the plasma to gradually decrease over time and cannot maintain a fixed photon count. In the period from 90 to 390 seconds of the control group, using two collimator sets to respectively monitor the two target holders and using two mass flow controller sets to respectively adjust the flow rate of oxygen supplied to the corresponding target holders according to the monitoring results of the corresponding target holders allows the light intensities of the plasmas of the first target holder and the second target holder to be substantially maintained at the preset 5000 photon counts. In the period from 90 to 390 seconds of the experimental group, using one collimator set to monitor the first target holder and using one mass flow controller set to adjust the flow rate of oxygen supplied to both target holders according to the monitoring result of the first target holder allows the light intensity of the plasma of the first target holder to be substantially maintained at the preset 5000 photon counts, and the light intensity of the plasma of the second target holder to be substantially maintained at about 4700-5000 photon counts. This shows that the light intensities of the plasmas provided by the two target holders in the sputtering system with a plasma monitoring device and an ion source of the experimental group can indeed be substantially the same or differ within 10%. Therefore, the applicant believes that the sputtering system with a plasma monitoring device and an ion source of the experimental group can replace the sputtering system with a plasma monitoring device and an ion source of the control group, achieving the effects of cost saving or system complexity reduction.

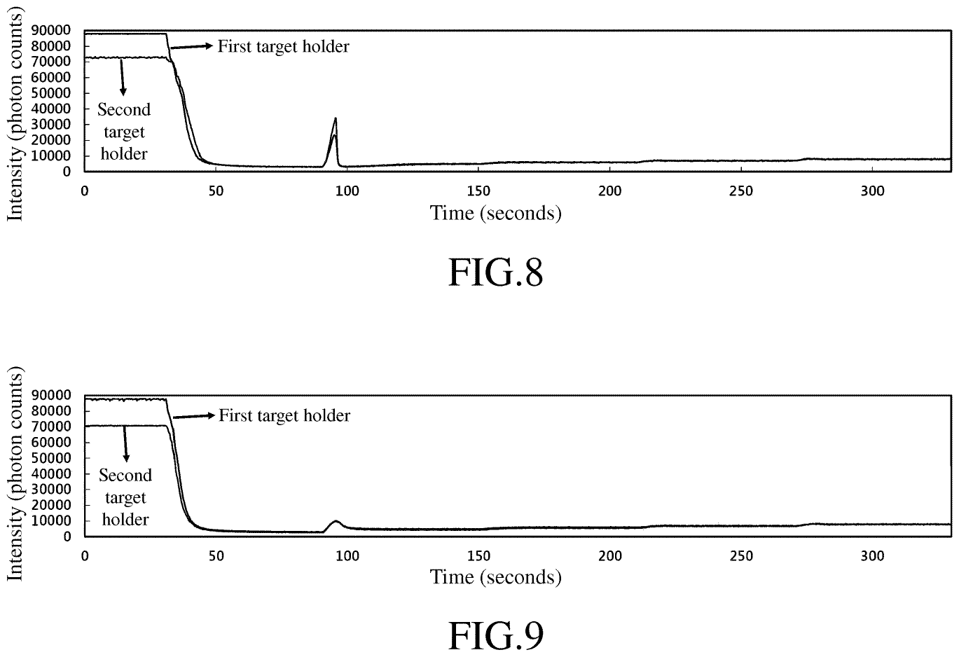

Then, please refer to both FIG. 8 and FIG. 9. FIG. 8 shows the plasma spectra of the two target holders in the control group when the light intensity of the plasma is preset to multiple photon count values. FIG. 9 shows the plasma spectra of the two target holders in the experimental group when the light intensity of the plasma is preset to multiple photon count values.

FIG. 8 and FIG. 9 show the results of detecting the plasma spectra at a wavelength of 453.6 nm (i.e., ionized titanium ions) of the plasmas provided by the two target holders. In the figures, the period from 0 to 30 seconds is the plasma spectrum of the plasma when no oxygen is provided; the period from 30 to 90 seconds is the plasma spectrum of the plasma when a fixed flow rate of oxygen is provided; the period from 90 to 150 seconds is the plasma spectrum when the flow rate of oxygen is adjusted according to the preset value (5000 photon counts) and real-time monitoring results; the period from 150 to 210 seconds is the plasma spectrum when the flow rate of oxygen is adjusted according to the preset value (6000 photon counts) and real-time monitoring results; the period from 210 to 270 seconds is the plasma spectrum when the flow rate of oxygen is adjusted according to the preset value (7000 photon counts) and real-time monitoring results; and the period from 270 to 330 seconds is the plasma spectrum when the flow rate of oxygen is adjusted according to the preset value (8000 photon counts) and real-time monitoring results. Additionally, the light intensities (photon counts) of the plasma detected at specific times in FIG. 8 are recorded in Table 3 below, and the light intensities (photon counts) of the plasma detected at specific times in FIG. 9 are recorded in Table 4 below.

TABLE 3

| | 30 s | 55 s | 90 s | 150 s | 210 s | 270 s | 330 s |
|---|---|---|---|---|---|---|---|
| First target | 87904 cts | 4087 cts | 3175 cts | 4936 cts | 5879 cts | 7154 cts | 8166 cts |
| holder | | | | | | | |
| Second target | 72597 cts | 4010 cts | 3026 cts | 4815 cts | 5872 cts | 7091 cts | 8043 cts |
| holder | | | | | | | |

TABLE 4

| | 30 s | 55 s | 90 s | 150 s | 210 s | 270 s | 330 s |
|---|---|---|---|---|---|---|---|
| First target | 86964 cts | 3722 cts | 3108 cts | 4852 cts | 6098 cts | 7060 cts | 8096 cts |
| holder | | | | | | | |
| Second target | 70760 cts | 3288 cts | 2545 cts | 4313 cts | 5537 cts | 6731 cts | 7934 cts |
| holder | | | | | | | |

From the results in Tables 3 and 4, it can be seen that in the period from 30 to 90 seconds of either the control group or the experimental group, providing a fixed flow rate of oxygen causes the light intensity of the plasma to gradually decrease over time and cannot maintain a fixed photon count. In the periods from 90 to 150 seconds, 150 to 210 seconds, 210 to 270 seconds, and 270 to 330 seconds of the control group, using two collimator sets to respectively monitor the two target holders and using two mass flow controller sets to respectively adjust the flow rate of oxygen supplied to the corresponding target holders according to the monitoring results of the corresponding target holders allows the light intensities of the plasmas of the first target holder and the second target holder to be substantially maintained at the preset photon counts. In the periods from 90 to 150 seconds, 150 to 210 seconds, 210 to 270 seconds, and 270 to 330 seconds of the experimental group, using one collimator set to monitor the first target holder and using one mass flow controller set to adjust the flow rate of oxygen supplied to both target holders according to the monitoring result of the first target holder allows the light intensity of the plasma of the first target holder to be substantially maintained at the preset photon count, and the light intensity of the plasma of the second target holder is also substantially maintained at the preset photon count. This shows that the light intensities of the plasmas provided by the two target holders in the sputtering system with a plasma monitoring device and an ion source of the experimental group can indeed be substantially the same or differ within 10%. Therefore, the applicant believes that the sputtering system with a plasma monitoring device and an ion source of the experimental group can replace the sputtering system with a plasma monitoring device and an ion source of the control group, achieving the effects of cost saving or system complexity reduction.

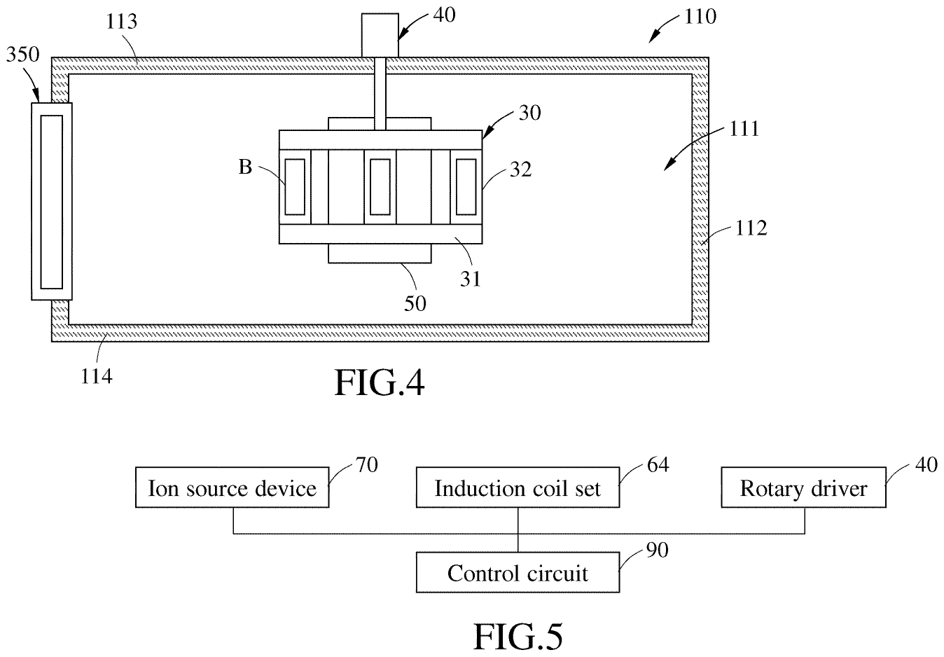

In addition, referring to FIGS. 3A, 3B, 4, and 5, the present application further includes:

A deposition target carrier 30 connected to the hollow chamber 110, disposed in the accommodating space 111, and used for carrying a deposition target B. Specifically, the deposition target carrier 30 includes, for example but not limited to, a holder 32 capable of carrying the deposition target B, and a support frame 31 connecting the holder 32 and the hollow chamber 110 (especially the top 113 or the bottom 114 of the hollow chamber 110). The support frame 31 is rotatably connected to a rotating shaft of a rotary driver 40 (such as but not limited to a motor). The present invention is not limited to the above-described aspect of the deposition target carrier 30.

A plasma source 60 connected to a side wall 112 of the hollow chamber 110 and used for providing an induced electric field to ionize the gas inside the hollow chamber 110. The plasma source 60 includes, for example but not limited to, a set of chamber doors 61 provided at an access port on the side wall 112 and an induction coil set 62 provided on the chamber door 61. The present invention is not limited to the above-described aspect of the plasma source 60.

An ion source device 70, which is a linear ion source, installed in the hollow chamber 110, particularly connected to the side wall 112 of the hollow chamber 110 and disposed in the accommodating space 111. The ion source device 70 is used to provide a stable high-energy ion beam. The rotary driver 40 has a rotation direction. The ion source device 70 is located on the front side of the rotation direction relative to the induction coil set 62, and the induction coil set 62 is located on the rear side of the rotation direction relative to the ion source device 70. By providing a stable high-energy ion beam via the ion source device 70, the density of the coating film layer is greatly increased, and the adhesion between target material atoms and the substrate is also improved.

Referring to FIG. 1, the power output line 191 of the power supply 190 can be connected to the induction coil set 62 and the ion source device 70. The power supply 190 may be of a DC, MF, RF, or HiPIMS type, but the invention is not limited thereto.

Referring to FIG. 5, a control circuit 90 is electrically connected to the rotary driver 40, the induction coil set 62, and the ion source device 70. The control circuit 90 can control the rotary driver 40 to drive the support frame 31 together with the holder 32 to rotate. The control circuit 90 can control the ion source device 70 to release a high-energy ion beam and enable the ion source device 70 and the first mass flow controller set 150 to be activated simultaneously. The control circuit 90 can control the induction coil set 62 to induce a high-frequency induced electric field. In this embodiment, the control circuit 90 is, for example but not limited to, a programmable logic controller (PLC).

In this embodiment, referring to FIGS. 3A and 3B, the rotary driver 40 drives the support frame 31 together with the holder 32 to rotate in a first direction D1. Through the first direction D1, a first direction front side and a first direction rear side are defined. For example, with reference to FIGS. 3A and 3B, the second target holder 130 on the right side of the drawing is located on the first direction front side relative to the induction coil set 62, and the first target holder 120 is located on the first direction rear side relative to the induction coil set 62. In this embodiment, the ion source device 70 is located on the first direction front side relative to the induction coil set 62. In other words, the ion source device 70 is located downstream of the induction coil set 62 along the path of the first direction D1, and the induction coil set 62 is located upstream of the ion source device 70 along the path of the first direction D1.

It is worth noting that during the sputtering process, the support frame 31 is in a state of rapid rotation, for example, 80-130 revolutions per minute or even faster. When the deposition target B passes by the first target holder 120 or the second target holder 130, metal atoms released from the first target material or the second target material first adhere to the deposition target B. Then, when the deposition target B passes by the plasma source 60, the induction coil set 62 of the plasma source 60 ionizes the reactive gas released from the first gas supply tube set 160 and the second gas supply tube set 170 into highly active ions, such as oxygen or nitrogen ions. The highly active ions then chemically react with the metal atoms to form an oxide or nitride film. The ion source device 70 located on the front side of the rotation direction physically bombards the above film with a high-energy ion beam to eliminate pores and increase the density of the film.

In addition, the high-energy ion beam from the ion source device 70 can also increase the plasma concentration, helping to suppress plasma energy decay and significantly improving plasma discharge stability and process continuity, thereby enhancing coating quality and increasing film density.

In summary, in the sputtering system with a plasma monitoring device and an ion source according to an embodiment of the present invention, because the first light intensity of the first plasma of the first target holder can still be substantially the same as the second light intensity of the second plasma of the second target holder even when the total number of collimator sets or mass flow controller sets is reduced, the sputtering system with a plasma monitoring device and an ion source according to an embodiment of the present invention can replace a conventional sputtering system with a plasma monitoring device and an ion source, achieving the effects of cost saving or system complexity reduction.

Furthermore, in an embodiment of the present invention, the ion source device 70 is additionally installed on the opposite side of the induction coil set 62 with respect to the rotation direction. By providing a stable high-energy ion beam through the ion source device 70, the density of the coating film layer is greatly increased, thereby achieving the effect of improving coating quality.

Although the present invention has been disclosed above with embodiments, they are not intended to limit the present invention. Any person having ordinary knowledge in the relevant technical field may make some modifications and alterations without departing from the spirit and scope of the present invention. Therefore, the protection scope of the present invention shall be defined by the appended claims.

What is claimed is:

1. A sputtering system with a plasma monitoring device and an ion source, comprising:
at least one first target holder located in a hollow chamber, the first target holder having a first target material and providing a first plasma;
at least one second target holder located in a hollow chamber, the second target holder having a second target material and providing a second plasma;
a first collimator set disposed corresponding to the first target holder to detect a first plasma spectrum of the first plasma;
a first mass flow controller set supplying gas to the first target holder and the second target holder through a first gas supply tube set and a second gas supply tube set, respectively;
a plasma emission monitor adjusting a flow rate of the gas provided by the first mass flow controller set according to the first plasma spectrum of the first plasma, wherein the first target material and the second target material are the same, and a total number of collimator sets is less than a total number of target holders, the first target holder corresponds to the independently disposed first gas supply tube set, and the second target holder corresponds to the independently disposed second gas supply tube set, a total number of gas supply tube sets is equal to the total number of target holders, the total number of gas supply tube sets is greater than the total number of collimator sets, and the total number of gas supply tube sets is greater than a total number of mass flow controller sets;
a deposition target carrier connected to the hollow chamber and configured to carry a deposition target;
a rotary driver rotatably connected to the deposition target carrier;
a plasma source connected to the hollow chamber and configured to provide an induced electric field to ionize the gas; and
an ion source device configured to provide an ion beam, wherein the rotary driver has a rotation direction, the ion source device is located on a front side of the rotation direction relative to the plasma source, and the plasma source is located on a rear side of the rotation direction relative to the ion source device.

2. The sputtering system as claimed in claim 1, wherein the total number of collimator sets is equal to 1, and the total number of target holders is greater than or equal to 2.

3. The sputtering system as claimed in claim 1, wherein the total number of mass flow controller sets is less than the total number of target holders.

4. The sputtering system as claimed in claim 3, wherein the total number of mass flow controller sets is equal to 1, and the total number of target holders is greater than or equal to 2.

5. The sputtering system as claimed in claim 1, wherein a first light intensity of the first plasma of the first target holder is the same as a second light intensity of the second plasma of the second target holder.

6. The sputtering system as claimed in claim 1, wherein a difference between a first light intensity of the first plasma of the first target holder and a second light intensity of the second plasma of the second target holder is within 10%.

7. The sputtering system as claimed in claim 1, further comprising:
at least one third target holder having a third target material and providing a third plasma; a second collimator set disposed corresponding to the third target holder to detect a third light intensity of the third plasma of the third target holder; and a second mass flow controller set supplying another gas to the third target holder through a third gas supply tube set, wherein the first target material is different from the third target material, and the total number of collimator sets is less than the total number of target holders.

8. The sputtering system as claimed in claim 7, wherein the total number of collimator sets is equal to 2, and the total number of target holders is greater than or equal to 3.

9. The sputtering system as claimed in claim 7, wherein the total number of mass flow controller sets is less than the total number of target holders.

10. The sputtering system as claimed in claim 9, wherein the total number of mass flow controller sets is equal to 2, and the total number of target holders is greater than or equal to 3.
